(19) United States
(12) Patent Application Publication
(10) Pub. No.: US 2026/0039085 A1
(43) Pub. Date: Feb. 5, 2026

(54) SURFACE-EMITTING LASER AND METHOD FOR MANUFACTURING THE SAME

(71) Applicant: KABUSHIKI KAISHA TOSHIBA, Tokyo (JP)

(72) Inventors: Tetsuya Miyagawa, Yokohama Kanagawa (JP); Rei Hashimoto, Edogawa Tokyo (JP); Shinji Saito, Yokohama Kanagawa (JP); Tsutomu Kakuno, Fujisawa Kanagawa (JP); Kei Kaneko, Yokohama Kanagawa (JP); Shinji Ookuma, Yokohama Kanagawa (JP); Masatoshi Hirono, Yokohama Kanagawa (JP)

(21) Appl. No.: 19/284,275

(22) Filed: Jul. 29, 2025

(30) Foreign Application Priority Data
Aug. 5, 2024 (JP) 2024-129033

(51) Int. Cl. H01S 5/11; H01S 5/183; H01S 5/323

(52) U.S. Cl. CPC H01S 5/11; H01S 5/3235; H01S 5/18305

(57) ABSTRACT

According to one embodiment, a surface-emitting laser includes first and second electrodes and a stacked body. The stacked body includes first to fourth crystal layers and a light-emitting layer. The first crystal layer includes a plurality of first structure bodies. The second crystal layer includes a plurality of second structure bodies. The light-emitting layer is provided between the first crystal layer and the second crystal layer. The third crystal layer is provided between the first crystal layer and the light-emitting layer. The second crystal layer is provided between the light-emitting layer and the fourth crystal layer.

### CROSS-REFERENCE TO RELATED APPLICATIONS

This application is based upon and claims the benefit of priority from Japanese Patent Application No. 2024-129033, filed on Aug. 5, 2024; the entire contents of which are incorporated herein by reference.

### FIELD

Embodiments described herein relate generally to a surface-emitting laser and a method for manufacturing the same.

### BACKGROUND

For example, in surface emitting lasers and the like, improvements in characteristics are desired.

### BRIEF DESCRIPTION OF THE DRAWINGS

FIGS. 1A and 1B are schematic cross-sectional views illustrating a surface-emitting laser according to the first embodiment;

FIGS. 2A and 2B are schematic plan views illustrating the surface-emitting laser according to the first embodiment;

FIG. 3 is a schematic cross-sectional view illustrating a part of the surface-emitting laser according to the first embodiment;

FIGS. 4A to 4F are schematic cross-sectional views illustrating a method for manufacturing a surface-emitting laser according to the second embodiment;

FIGS. 5A to 5D are schematic cross-sectional views illustrating a method for manufacturing a surface-emitting laser according to the second embodiment; and

FIG. 6A to FIG. 6D are schematic cross-sectional views illustrating a method for manufacturing a surface-emitting laser according to the second embodiment.

### DETAILED DESCRIPTION

According to one embodiment, a surface-emitting laser includes a first electrode, a second electrode, and a stacked body provided between the first electrode and the second electrode. The stacked body includes a first crystal layer, a second crystal layer, a light-emitting layer, a third crystal layer, and fourth crystal layer. The first crystal layer includes a plurality of first structure bodies arranged two-dimensionally along a first plane. A first direction from the first crystal layer to the second crystal layer crosses the first plane. The second crystal layer includes a plurality of second structure bodies two-dimensionally arranged along the first plane. The light-emitting layer is provided between the first crystal layer and the second crystal layer. The third crystal layer is provided between the first crystal layer and the light-emitting layer. The third crystal layer includes a first partial region and a second partial region. The first partial region is provided between the plurality of first structure bodies and the light-emitting layer. The second partial region is provided between the plurality of first structure bodies. A refractive index of the third crystal layer is different from a refractive index of the first crystal layer. The second crystal layer is provided between the light-emitting layer and the fourth crystal layer. The fourth crystal layer includes a third partial region and a fourth partial region. The plurality of second structure bodies are provided between the light-emitting layer and the third partial region. The fourth partial region is provided between the plurality of second structure bodies. A refractive index of the fourth crystal layer is different from a refractive index of the second crystal layer.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

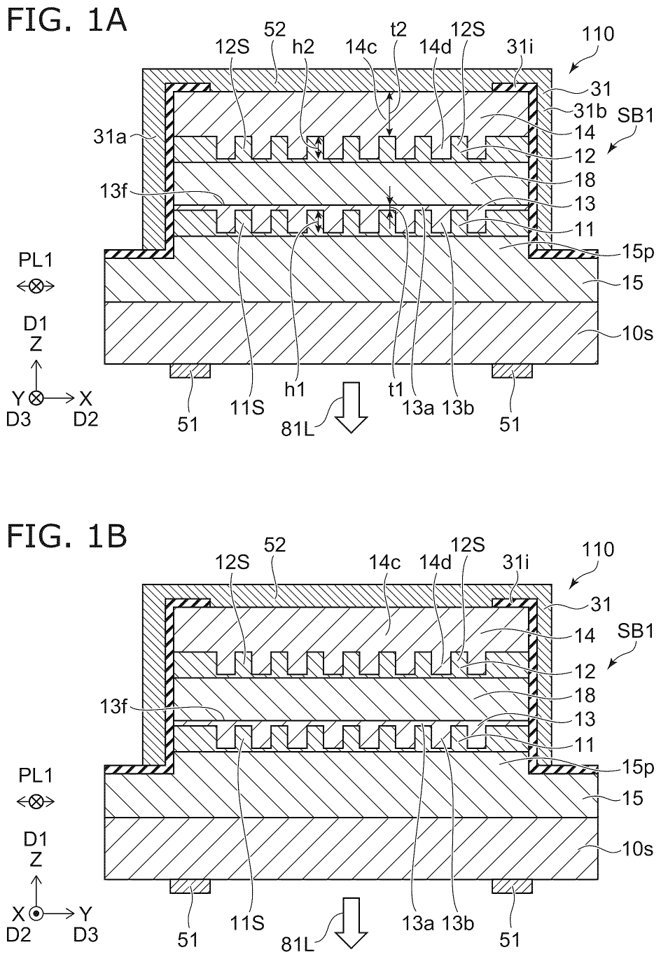

FIGS. 1A and 1B are schematic cross-sectional views illustrating a surface-emitting laser according to the first embodiment.

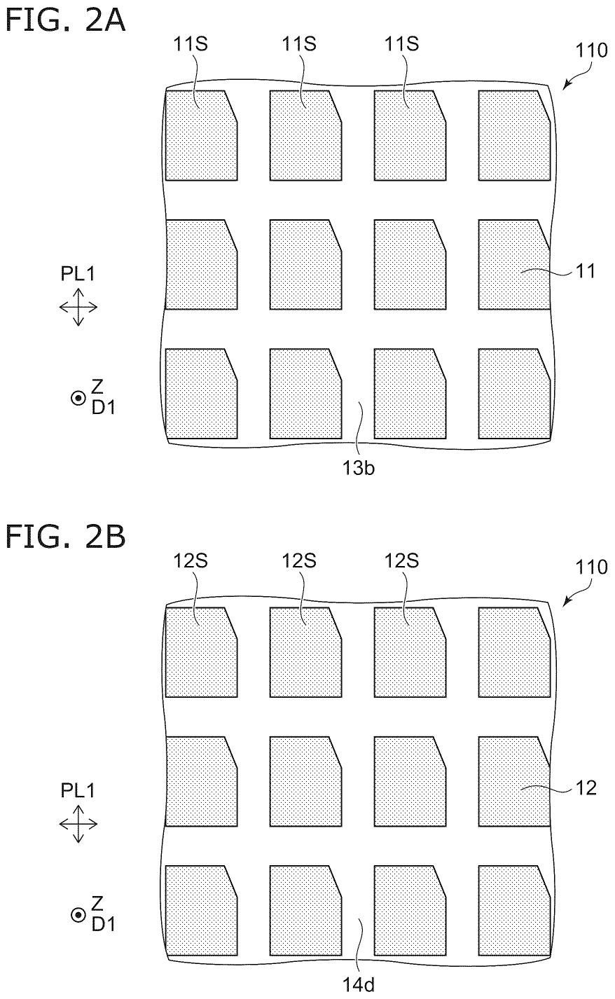

FIGS. 2A and 2B are schematic plan views illustrating the surface-emitting laser according to the first embodiment.

As shown in FIGS. 1A and 1B, a surface-emitting laser 110 according to the embodiment includes a first electrode 51, a second electrode 52, and a stacked body SB1. The stacked body SB1 is provided between the first electrode 51 and the second electrode 52.

The stacked body SB1 includes a first crystal layer 11, a second crystal layer 12, a third crystal layer 13, a fourth crystal layer 14, and a light-emitting layer 18. The first crystal layer 11 includes a plurality of first structure bodies 11S. The plurality of first structure bodies 11S are arranged two-dimensionally along a first plane PL1.

A first direction D1 from the first crystal layer 11 to the second crystal layer 12 crosses the first plane PL1. For example, the first direction D1 may be perpendicular to the first plane PL1. The first direction D1 is defines as a Z-axis direction. One direction perpendicular to the Z-axis direction is defines as an X-axis direction. A direction perpendicular to the Z-axis direction and the X-axis direction is defined as a Y-axis direction. The first plane PL1 is along the X-Y plane. The first direction D1 corresponds to the stacking direction of the stacked body SB1.

FIG. 1A corresponds to a cross-sectional view taken along the Z-X plane. FIG. 1B corresponds to a cross-sectional view taken along the Z-Y plane.

The second crystal layer 12 includes a plurality of second structure bodies 12S. The plurality of second structure bodies 12S are arranged two-dimensionally along the first plane PL1. The plurality of first structure bodies 11S and the plurality of second structure bodies 12S are arranged along the second direction D2. The second direction D2 crosses the first direction D1. The plurality of first structure bodies 11S and the plurality of second structure bodies 12S are arranged along the third direction D3. The third direction D3 crosse, for example, a plane including the first direction D1 and the second direction D2.

FIG. 2A illustrates the plurality of first structure bodies 11S. FIG. 2B illustrates the plurality of second structure bodies 12S.

As shown in FIGS. 1A and 1B, the light-emitting layer 18 is provided between the first crystal layer 11 and the second crystal layer 12. The light-emitting layer 18 is, for example, an active layer. In one example, the light-emitting layer 18 may include a plurality of quantum well structure (not shown).

The third crystal layer 13 is provided between the first crystal layer 11 and the light-emitting layer 18. The third crystal layer 13 includes a first partial region 13a and a second partial region 13b. The first partial region 13a is provided between the plurality of first structure bodies 11S and the light-emitting layer 18. The second partial region 13b is provided between two of the plurality of first structure bodies 11S. For example, the first partial region 13a is provided between the plurality of first structure bodies 11S and the light-emitting layer 18 in the first direction D1. The second partial region 13b is provided between two of the plurality of first structure bodies 11S in the direction along the first plane PL1. The refractive index of the third crystal layer 13 is different from the refractive index of the first crystal layer 11.

The second crystal layer 12 is provided between the light-emitting layer 18 and the fourth crystal layer 14. The fourth crystal layer 14 includes a third partial region 14c and a fourth partial region 14d. The second structure bodies 12S are provided between the light-emitting layer 18 and the third partial region 14c. The fourth partial region 14d is provided between two of the second structure bodies 12S. For example, the second structure bodies 12S are provided between the light-emitting layer 18 and the third partial region 14c in the first direction D1. For example, the fourth partial region 14d is provided between two of the second structure bodies 12S in the direction along the first plane PL1. The refractive index of the fourth crystal layer 14 is different from the refractive index of the second crystal layer 12.

In this embodiment, the first crystal layer 11 and the third crystal layer 13 function as one photonic crystal layer. The second crystal layer 12 and the fourth crystal layer 14 function as another photonic crystal layer. The light-emitting layer 18 is provided between the two photonic crystal layers. A current is supplied between the first electrode 51 and the second electrode 52. Thereby, light is emitted from the light-emitting layer 18. The emitted light is efficiently directed toward the emission face by the two photonic crystals. For example, the light is efficiently extracted to the outside.

According to the embodiment, highly efficient light emission can be obtained. For example, light of a substantially single wavelength can be obtained with high efficiency. According to the embodiment, a surface-emitting laser capable of improving characteristics can be provided. According to the embodiment, for example, the controllability of the photonic band gap in the photonic crystal can be improved.

For example, the light-emitting layer 18 emits light based on intersubband transition. For example, higher efficiency can be obtained. The surface-emitting laser 110 is, for example, a surface-emitting quantum cascade laser (QCL).

The material of the first crystal layer 11 is different from the material of the third crystal layer 13. This results in a difference in refractive index. The material of the second crystal layer 12 is different from the material of the fourth crystal layer 14. This results in a difference in refractive index.

In one example, at least one of the first crystal layer 11 or the second crystal layer 12 includes InGaAs. The refractive index of these crystal layers is, for example, about 3.4. At least one of the third crystal layer 13 or the fourth crystal layer 14 includes InP. The refractive index of these crystal layers is, for example, 3.1. The refractive index may be, for example, the refractive index of the wavelength of the light emitted from the light-emitting layer 18.

For example, the third crystal layer 13 contacts the first crystal layer 11 and the light-emitting layer 18. The second crystal layer 12 contacts the light-emitting layer 18 and the fourth crystal layer 14. A part of the third crystal layer 13 (second partial region 13b) is embedded between the plurality of first structure bodies 11S. A part of the fourth crystal layer 14 (fourth partial region 14d) is embedded between the plurality of second structure bodies 12S.

In the embodiment, the first partial region 13a of the third crystal layer 13 is provided. This makes it easier to obtain good crystallinity in the light-emitting layer 18 provided on the third crystal layer 13. For example, if the first partial region 13a is not provided, the light-emitting layer 18 is formed on the plurality of first structure bodies 11S and the second partial region 13b. It is practically difficult to form the light-emitting layer 18 with good crystallinity on a different material. By covering the plurality of first structure bodies 11S with the third crystal layer 13, high crystallinity can be obtained in the light-emitting layer 18 formed thereon.

From the viewpoint of high crystallinity in the light-emitting layer 18, it is preferable that the first partial region 13a is thick. On the other hand, as already explained, the first crystal layer 11 and the third crystal layer 13 form one photonic crystal layer. It is preferable that the distance between this photonic crystal layer and the light-emitting layer 18 is short. This allows the light emitted from the light-emitting layer 18 to be efficiently affected by the photonic crystal layer. From this viewpoint, it is preferable that the first partial region 13a is thin.

As shown in FIG. 1A, a thickness of the first partial region 13a along the first direction D1 is defined as a first thickness t1. For example, the first thickness t1 is preferably not less than 0.05 μm and less than 1 μm. When the first thickness t1 is not less than 0.05 μm, for example, it becomes easy to obtain the light-emitting layer 18 with good crystallinity. When the first thickness t1 is less than 1 μm, for example, it becomes easy to efficiently obtain the effect of controlling light by the photonic crystal. The first thickness t1 may not more than 0.8 μm, for example.

On the other hand, the third partial region 14c of the fourth crystal layer 14 functions as a cladding layer. It is preferable that the third partial region 14c is appropriately thick. This allows the light trapping effect of the cladding layer to be efficiently obtained.

As shown in FIG. 1A, a thickness of the third partial region 14c along the first direction D1 is defined as a second thickness t2. The second thickness t2 is preferably, for example, not less than 1 μm and not more than 10 μm. When the second thickness t2 is not less than 1 μm, it becomes easy to obtain an appropriate function as a cladding layer. When the second thickness t2 is not more than 10 μm, for example, absorption is suppressed and a high efficiency becomes easy to be obtained.

Thus, it is preferable that the first thickness t1 is thinner than the second thickness t2. This makes it easier to obtain high crystallinity and high efficiency.

As shown in FIGS. 1A and 1B, the third crystal layer 13 includes a first face 13f. The first face 13f contacts the light-emitting layer 18. It is preferable that the first face 13f is flat. For example, the root-mean-square roughness (RMS) of the first face 13f is preferably less than 1 nm. With a surface flatness having a root-mean-square roughness of less than 1 nm, for example, good crystal growth is easily obtained. It is more preferable that the root-mean-square roughness of the first face 13f is less than 0.1 nm. This makes it easier to obtain a good thin periodic structure in the light-emitting layer 18 formed on the first face 13f. It is more preferable that the root-mean-square roughness of the first face 13f is less than 0.03 nm. It is easier to obtain the light-emitting layer 18 with further better characteristics.

As shown in FIG. 1A, a height of the plurality of second structure bodies 12S along the first direction D1 is defined as a second height h2. A height of the plurality of first structure bodies 11S along the first direction D1 is defined as a first height h1. The higher these heights are, the higher the controllability of the light. On the other hand, if the first height h1 is made higher, it becomes difficult to obtain high flatness on the first face 13f. In the embodiment, the second height h2 may be higher than the first height h1. This makes it easier to obtain high efficiency.

As shown in FIGS. 1A and 1B, it is preferable that the positions of the plurality of second structure bodies 12S in the first plane PL1 substantially coincide with the positions of the plurality of first structure bodies 11S in the first plane PL1. This causes the phase in the photonic crystal layer including the plurality of first structure bodies 11S to coincide with the phase in the photonic crystal layer including the plurality of second structure bodies 12S. More efficient control of light can be obtained.

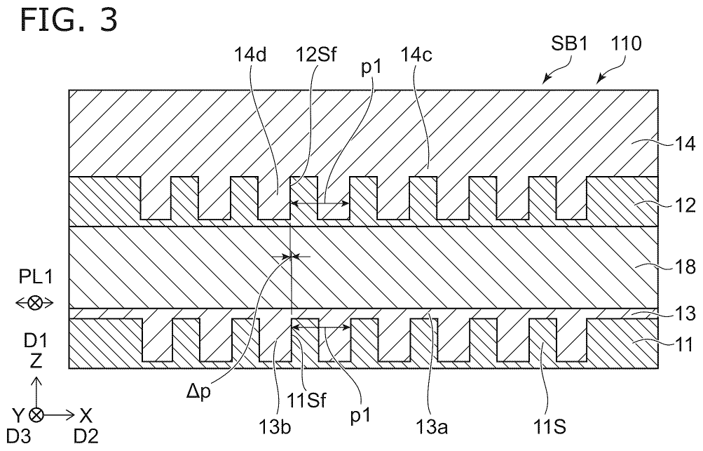

FIG. 3 is a schematic cross-sectional view illustrating a part of the surface-emitting laser according to the first embodiment.

FIG. 3 illustrates an enlarged view of the stacked body SB1. As shown in FIG. 3, parts of the plurality of first structure bodies 11S are aligned at a first pitch p1 along the second direction D2 along the first plane PL1. Parts of the plurality of second structure bodies 12S are aligned at a first pitch p1 along the second direction D2. By aligning these plurality of structure bodies at the same pitch, the positions of these structure bodies on the first plane PL1 are the same. In one example, the second direction D2 may be the X-axis direction.

As shown in FIG. 3, one of the plurality of first structure bodies 11S includes a first structure body side face 11Sf facing the second partial region 13b. One of the plurality of second structure bodies 12S includes a second structure body side face 12Sf facing the fourth partial region 14d. At least a part of one of the plurality of first structure bodies 11S overlaps one of the plurality of second structure bodies 12S in the first direction D1.

A distance Δp in the second direction D2 between the position of the first structure body side face 11Sf in the second direction D2 and the position of the second structure body side face 12Sf in the second direction D2 corresponds to an amount of shift in the pattern. The amount of shift is not necessarily zero due to non-uniformity in the manufacturing process. In the embodiment, the distance Δp (amount of shift) is preferably, for example, 0.1 times or less the first pitch p1. This allows high efficiency to be maintained.

As shown in FIGS. 1A and 1B, the stacked body SB1 may further include a fifth crystal layer 15. The first crystal layer 11 is provided between a portion 15p of the fifth crystal layer 15 and the light-emitting layer 18. This allows a ridge structure (mesa structure) to be appropriately provided. For example, a current confinement structure is appropriately obtained. In one example, the fifth crystal layer 15 includes InP. The fifth crystal layer 15 may correspond to, for example, a cladding layer.

As shown in FIGS. 1A and 1B, the stacked body SB1 may further include a substrate 10s. For example, the substrate 10s is provided between the first electrode 51 and the first crystal layer 11. The fifth crystal layer 15 is provided between the substrate 10s and the first crystal layer 11. In one example, the substrate 10s includes InP. For example, the light 81L is emitted from a face of the substrate 10s facing the first electrode 51. This face corresponds to the emission face.

As shown in FIGS. 1A and 1B, the surface-emitting laser 110 may further include a reflective film 31. The reflective film 31 includes a first reflective region 31a and a second reflective region 31b. The first crystal layer 11, the second crystal layer 12, the light-emitting layer 18, the third crystal layer 13, and the fourth crystal layer 14 are provided between the first reflective region 31a and the second reflective region 31b along the first plane PL1. By providing the reflective film 31, light is used efficiently. The reflectance of the reflective film 31 is higher than the reflectance of the stacked body SB1.

The reflective film 31 may be continuous with, for example, the second electrode 52. At least one of the first electrode 51, the second electrode 52, or the reflective film 31 may include a metal such as Au.

As shown in FIGS. 1A and 1B, the surface-emitting laser 110 may further include an insulating film 31i. A part of the insulating film 31i is provided between the first crystal layer 11, the second crystal layer 12, the light-emitting layer 18, the third crystal layer 13, and the fourth crystal layer 14, and the first reflective region 31a. Another part of the insulating film 31i is provided between the first crystal layer 11, the second crystal layer 12, the light-emitting layer 18, the third crystal layer 13, and the fourth crystal layer 14, and the second reflective region 31b. The insulating film 31i includes, for example, at least one selected from the group consisting of silicon and aluminum, and at least one selected from the group consisting of oxygen and nitrogen. The insulating film 31i may include, for example, silicon oxide, etc.

In the embodiment, the plurality of first structure bodies 11S and the plurality of second structure bodies 12S may be arranged, for example, in any of a square lattice array, a rectangular lattice array, and a triangular lattice array.

### Second Embodiment

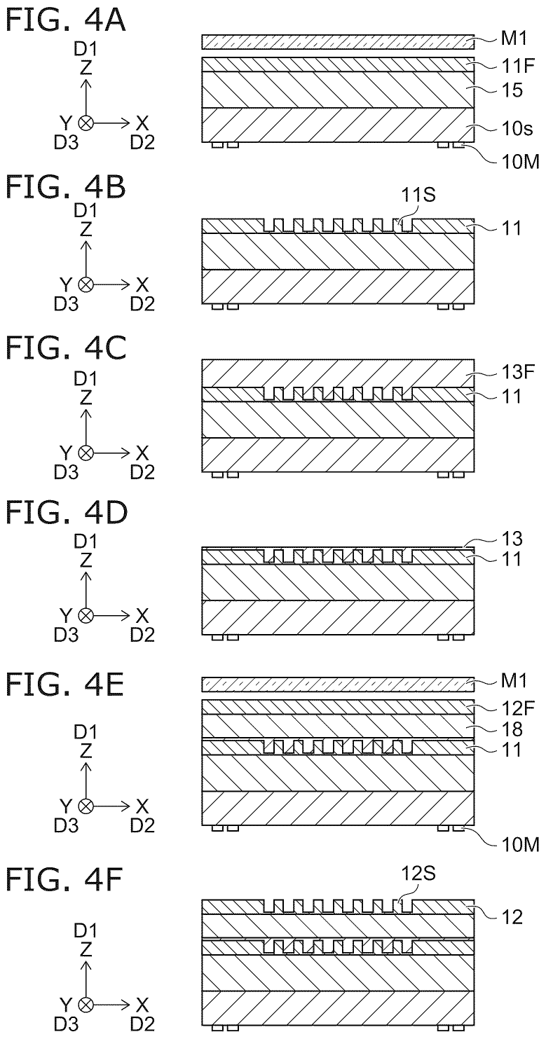

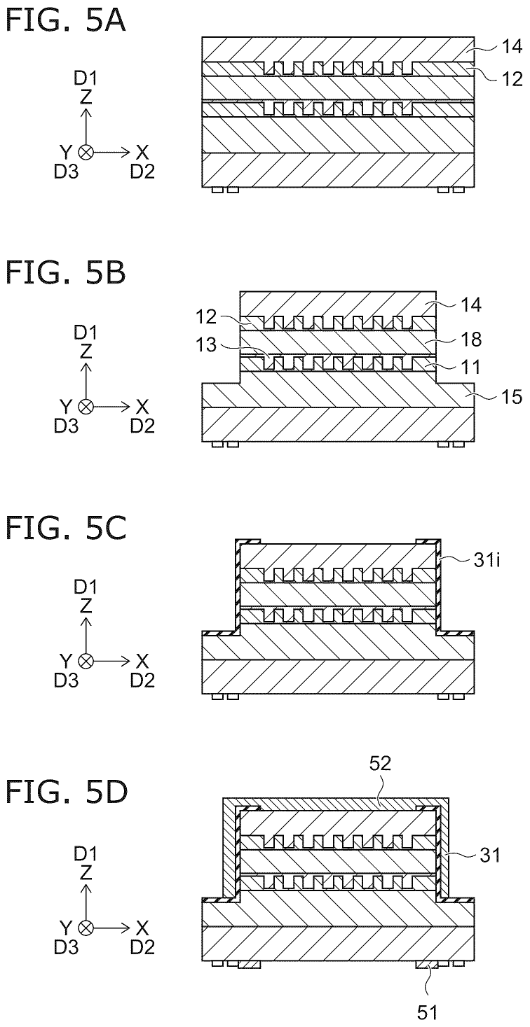

FIGS. 4A to 4F and 5A to 5D are schematic cross-sectional views illustrating a method for manufacturing a surface-emitting laser according to the second embodiment.

As shown in FIG. 4A, for example, the fifth crystal layer 15 is provided on the substrate 10s. The first crystal film 11F is provided on the fifth crystal layer 15. An alignment mark 10M is provided on the lower surface of the substrate 10s. The first crystal film 11F is processed using a first mask M1. For example, photolithography using the first mask M1 and etching (for example, dry etching) are performed. For example, the alignment mark 10M is used.

As a result, as shown in FIG. 4B, the first crystal layer 11 including the plurality of first structure bodies 11S is formed from the first crystal film 11F.

As shown in FIG. 4C, a third crystal film 13F is formed on the first crystal layer 11. The refractive index of the third crystal film 13F is different from the refractive index of the first crystal layer 11.

As shown in FIG. 4D, the surface of the third crystal film 13F is planarized. For example, CMP (Chemical Mechanical Polishing) is performed. The third crystal film 13F may be thinned. As a result, the third crystal layer 13 is formed from the third crystal film 13F.

As shown in FIG. 4E, the light-emitting layer 18 is formed on the third crystal layer 13. Furthermore, a second crystal film 12F is formed on the light-emitting layer 18. The second crystal film 12F is processed using the first mask M1. For example, photolithography using the first mask M1 and etching (e.g., dry etching) are performed. For example, the alignment mark 10M is used.

As a result, the second crystal layer 12 including a plurality of second structure bodies 12S is formed from the second crystal film 12F, as shown in FIG. 4F.

As shown in FIG. 5A, the fourth crystal layer 14 is formed on the second crystal layer 12. The refractive index of the fourth crystal layer 14 is different from the refractive index of the second crystal layer 12.

As shown in FIG. 5B, a part of the above crystal layers are partially removed to form the mesa structure. As shown in FIG. 5C, the insulating film 31i is formed. As shown in FIG. 5D, the reflective film 31 is formed. At this time, the second electrode 52 may be formed. The first electrode 51 is formed. Through such processing, for example, the surface-emitting laser 110 is obtained.

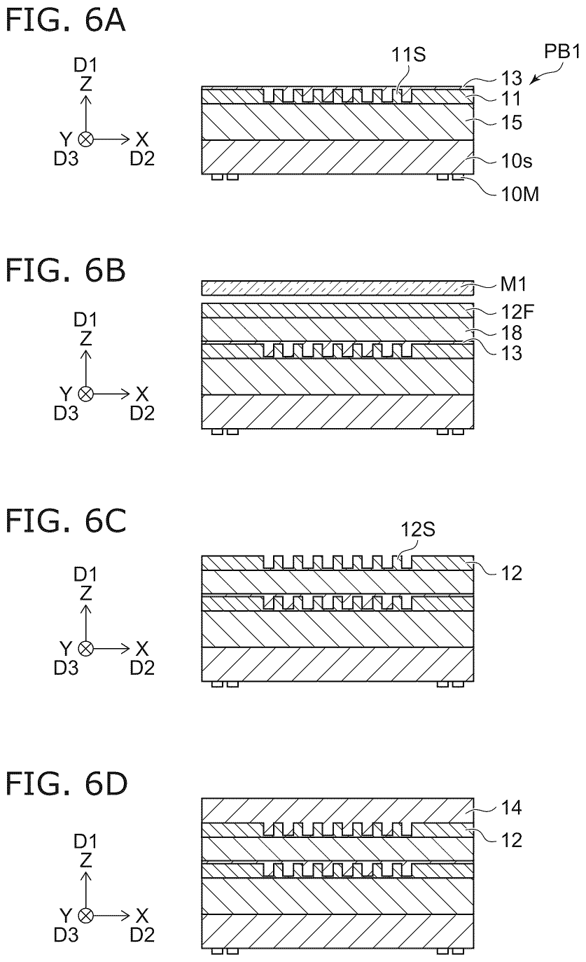

FIG. 6A to FIG. 6D are schematic cross-sectional views illustrating a method for manufacturing a surface-emitting laser according to the second embodiment.

As shown in FIG. 6A, a workpiece PB1 is prepared. The workpiece PB1 includes the first crystal layer 11 including the plurality of first structure bodies 11S, and the third crystal layer 13 provided on the first crystal layer 11. The refractive index of the third crystal layer 13 is different from that of the first crystal layer 11. For example, the surface of the third crystal layer 13 may be flattened. For example, the root-mean-square roughness (RMS) of the first face 13f is preferably less than 1 nm. By the surface flatness with a root-mean-square roughness of less than 1 nm, it becomes easy to obtain, for example, good crystal growth. It is more preferable that the root-mean-square roughness of the first face 13f is less than 0.1 nm. This makes it easy to obtain a good thin periodic structure in the light-emitting layer 18 formed on the first face 13f. It is more preferable that the root mean square roughness of the first face 13f is less than 0.03 nm. The light-emitting layer 18 with further better characteristics can be easily obtained.

As shown in FIG. 6B, the light-emitting layer 18 is formed on the third crystal layer 13. Furthermore, the second crystal film 12F is formed on the light-emitting layer 18. The second crystal film 12F is processed.

As a result, as shown in FIG. 6C, the second crystal layer 12 including the plurality of second structure bodies 12S is formed from the second crystal film 12F. The second pattern of the plurality of second structure bodies 12S is the same as the first pattern of the plurality of first structure bodies 11S.

As shown in FIG. 6D, the fourth crystal layer 14 is formed on the second crystal layer 12. The refractive index of the fourth crystal layer 14 is different from the refractive index of the second crystal layer 12. Thereafter, by performing the processes described with reference to FIG. 5B to FIG. 5D, for example, the surface-emitting laser 110 is obtained.

Embodiments may include the following Technical proposals:

### (Technical Proposal 1)

A surface-emitting laser, comprising:
a first electrode;
a second electrode; and
a stacked body provided between the first electrode and the second electrode,
the stacked body including:
   a first crystal layer including a plurality of first structure bodies arranged two-dimensionally along a first plane,
   a second crystal layer, a first direction from the first crystal layer to the second crystal layer crossing the first plane, the second crystal layer including a plurality of second structure bodies two-dimensionally arranged along the first plane,
   a light-emitting layer provided between the first crystal layer and the second crystal layer,
   a third crystal layer provided between the first crystal layer and the light-emitting layer, the third crystal layer including a first partial region and a second partial region, the first partial region being provided between the plurality of first structure bodies and the light-emitting layer, the second partial region being provided between the plurality of first structure bodies, a refractive index of the third crystal layer being different from a refractive index of the first crystal layer, and
   a fourth crystal layer, the second crystal layer being provided between the light-emitting layer and the fourth crystal layer, the fourth crystal layer including a third partial region and a fourth partial region, the plurality of second structure bodies being provided between the light-emitting layer and the third partial region, the fourth partial region being provided between the plurality of second structure bodies, a refractive index of the fourth crystal layer being different from a refractive index of the second crystal layer.

### (Technical Proposal 2)

The surface-emitting laser according to Technical proposal 1, wherein
a first thickness of the first partial region along the first direction is smaller than a second thickness of the third partial region along the first direction.

### (Technical Proposal 3)

The surface-emitting laser according to Technical proposal 2, wherein
the first thickness is not less than 0.05 μm and less than 1 μm.

### (Technical Proposal 4)

The surface-emitting laser according to Technical proposal 3, wherein
the second thickness is not less than 1 μm and not more than 10 μm.

### (Technical Proposal 5)

The surface-emitting laser according to any one of Technical proposals 1-4, wherein
the third crystal layer includes a first face contacting the light-emitting layer, and
a root-mean-square roughness of the first face is 1 nm or less.

### (Technical Proposal 6)

The surface-emitting laser according to any one of Technical proposals 1-5, wherein
a second height of the plurality of second structure bodies along the first direction is greater than a first height of the plurality of first structure bodies along the first direction.

### (Technical Proposal 7)

The surface-emitting laser according to any one of Technical proposals 1-6, wherein
positions of the plurality of second structure bodies in the first plane substantially coincide with positions of the plurality of first structure bodies in the first plane.

### (Technical Proposal 8)

The surface-emitting laser according to any one of Technical proposals 1-7, wherein
parts of the plurality of first structure bodies are arranged at a first pitch along a second direction along the first plane, and
parts of the plurality of second structure bodies are arranged at the first pitch along the second direction.

### (Technical Proposal 9)

The surface-emitting laser according to any one of Technical proposal 8, wherein
one of the first structure bodies includes a first structure body side face facing the second partial region,
one of the second structure bodies includes a second structure body side face facing the fourth partial region,
at least a part of the one of the plurality of first structure bodies overlaps the one of the plurality of second structure bodies in the first direction,
a distance in the second direction between a position of the first structure body side face in the second direction and a position of the second structure body side face in the second direction is 0.1 times or less the first pitch.

### (Technical Proposal 10)

The surface-emitting laser according to any one of Technical proposals 1-9, wherein
the third crystal layer is in contact with the first crystal layer and the light-emitting layer, and
the second crystal layer is in contact with the light-emitting layer and the fourth crystal layer.

### (Technical Proposal 11)

The surface-emitting laser according to any one of Technical proposals 1-10, wherein
at least one of the first crystal layer or the second crystal layer includes InGaAs, and
at least one of the third crystal layer or the fourth crystal layer includes InP.

### (Technical Proposal 12)

The surface-emitting laser according to any one of Technical proposals 1-11, wherein
the stacked body further includes a fifth crystal layer, and
the first crystal layer is provided between a portion of the fifth crystal layer and the light-emitting layer.

### (Technical Proposal 13)

The surface-emitting laser according to Technical proposal 12, wherein
the fifth crystal layer includes InP.

### (Technical Proposal 14)

The surface-emitting laser according to Technical proposal 12 or 13, wherein
the stacked body further includes a substrate, and
the fifth crystal layer is provided between the substrate and the first crystal layer.

### (Technical Proposal 15)

The surface-emitting laser according to any one of Technical proposals 1-14, further comprising:
a reflective film including a first reflective region and a second reflective region, and
the first crystal layer, the second crystal layer, the light-emitting layer, the third crystal layer, and the fourth crystal layer are provided between the first reflective region and the second reflective region along the first plane.

### (Technical Proposal 16)

The surface-emitting laser according to Technical proposal 15, further comprising:
an insulating film,
a part of the insulating film being provided between a stacked layer and the first reflective region, the stacked layer including the first crystal layer, the second crystal layer, the light-emitting layer, the third crystal layer, and the fourth crystal layer, and
another part of the insulating film being provided between the stacked layer and the second reflective region.

### (Technical Proposal 17)

The surface-emitting laser according to any one of Technical proposals 1-16, wherein
the plurality of first structure bodies and the plurality of second structure bodies are arranged in one of a square lattice array, a rectangular lattice array, and a triangular lattice array.

### (Technical Proposal 18)

The surface-emitting laser according to any one of Technical proposals 1-17, wherein
the light-emitting layer is configured to emit light based on intersubband transition.

### (Technical Proposal 19)

A method for manufacturing a surface-emitting laser, comprising:
processing a first crystal film using a first mask to form a first crystal layer including a plurality of first structure bodies;
forming a third crystal film on the first crystal layer, a refractive index of the third crystal film being different from a refractive index of the first crystal layer;
planarizing a surface of the third crystal film to form a third crystal layer from the third crystal film;
forming a light-emitting layer on the third crystal layer;
forming a second crystal film on the light-emitting layer;
processing the second crystal film using the first mask to form a second crystal layer including a plurality of second structure bodies; and
forming a fourth crystal layer on the second crystal layer, a refractive index of the fourth crystal layer being different from a refractive index of the second crystal layer.

### (Technical Proposal 20)

A method for manufacturing a surface-emitting laser, comprising:
preparing a workpiece including a first crystal layer including a plurality of first structure bodies and a third crystal layer provided on the first crystal layer, a refractive index of the third crystal layer being different from a refractive index of the first crystal layer;
forming a light-emitting layer on the third crystal layer;
forming a second crystal film on the light-emitting layer;
processing the second crystal film Oto form a second crystal layer including a plurality of second structure bodies, a second pattern of the plurality of second structure bodies being the same as a first pattern of the plurality of first structure bodies; and
forming a fourth crystal layer on the second crystal layer, a refractive index of the fourth crystal layer being different from a refractive index of the second crystal layer.

According to the embodiment, a surface-emitting laser capable of improving characteristics and a method for manufacturing the same can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in surface-emitting lasers such as electrode, stacked bodies, crystal layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all surface-emitting lasers and all methods for manufacturing the same practicable by an appropriate design modification by one skilled in the art based on the surface-emitting lasers and all methods for manufacturing the same described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A surface-emitting laser, comprising:
a first electrode;
a second electrode; and
a stacked body provided between the first electrode and the second electrode,
the stacked body including:
a first crystal layer including a plurality of first structure bodies arranged two-dimensionally along a first plane,
a second crystal layer, a first direction from the first crystal layer to the second crystal layer crossing the first plane, the second crystal layer including a plurality of second structure bodies two-dimensionally arranged along the first plane,
a light-emitting layer provided between the first crystal layer and the second crystal layer,
a third crystal layer provided between the first crystal layer and the light-emitting layer, the third crystal layer including a first partial region and a second partial region, the first partial region being provided between the plurality of first structure bodies and the light-emitting layer, the second partial region being provided between the plurality of first structure bodies, a refractive index of the third crystal layer being different from a refractive index of the first crystal layer, and
a fourth crystal layer, the second crystal layer being provided between the light-emitting layer and the fourth crystal layer, the fourth crystal layer including a third partial region and a fourth partial region, the plurality of second structure bodies being provided between the light-emitting layer and the third partial region, the fourth partial region being provided between the plurality of second structure bodies, a refractive index of the fourth crystal layer being different from a refractive index of the second crystal layer.

2. The surface-emitting laser according to claim 1, wherein
a first thickness of the first partial region along the first direction is smaller than a second thickness of the third partial region along the first direction.

3. The surface-emitting laser according to claim 2, wherein
the first thickness is not less than 0.05 μm and less than 1 μm.

4. The surface-emitting laser according to claim 3, wherein
the second thickness is not less than 1 μm and not more than 10 μm.

5. The surface-emitting laser according to claim 1, wherein
the third crystal layer includes a first face contacting the light-emitting layer, and
a root-mean-square roughness of the first face is 1 nm or less.

6. The surface-emitting laser according to claim 1, wherein
a second height of the plurality of second structure bodies along the first direction is greater than a first height of the plurality of first structure bodies along the first direction.

7. The surface-emitting laser according to claim 1, wherein
positions of the plurality of second structure bodies in the first plane substantially coincide with positions of the plurality of first structure bodies in the first plane.

8. The surface-emitting laser according to claim 1, wherein
parts of the plurality of first structure bodies are arranged at a first pitch along a second direction along the first plane, and
parts of the plurality of second structure bodies are arranged at the first pitch along the second direction.

9. The surface-emitting laser according to claim 8, wherein
one of the first structure bodies includes a first structure body side face facing the second partial region,
one of the second structure bodies includes a second structure body side face facing the fourth partial region,
at least a part of the one of the plurality of first structure bodies overlaps the one of the plurality of second structure bodies in the first direction,
a distance in the second direction between a position of the first structure body side face in the second direction and a position of the second structure body side face in the second direction is 0.1 times or less the first pitch.

10. The surface-emitting laser according to claim 1, wherein
the third crystal layer is in contact with the first crystal layer and the light-emitting layer, and
the second crystal layer is in contact with the light-emitting layer and the fourth crystal layer.

11. The surface-emitting laser according to claim 1, wherein
at least one of the first crystal layer or the second crystal layer includes InGaAs, and
at least one of the third crystal layer or the fourth crystal layer includes InP.

12. The surface-emitting laser according to claim 1, wherein
the stacked body further includes a fifth crystal layer, and
the first crystal layer is provided between a portion of the fifth crystal layer and the light-emitting layer.

13. The surface-emitting laser according to claim 12, wherein
the fifth crystal layer includes InP.

14. The surface-emitting laser according to claim 12, wherein
the stacked body further includes a substrate, and
the fifth crystal layer is provided between the substrate and the first crystal layer.

15. The surface-emitting laser according to claim 1, further comprising:
a reflective film including a first reflective region and a second reflective region, and
the first crystal layer, the second crystal layer, the light-emitting layer, the third crystal layer, and the fourth crystal layer are provided between the first reflective region and the second reflective region along the first plane.

16. The surface-emitting laser according to claim 15, further comprising:
an insulating film,
a part of the insulating film being provided between a stacked layer and the first reflective region, the stacked layer including the first crystal layer, the second crystal layer, the light-emitting layer, the third crystal layer, and the fourth crystal layer, and
another part of the insulating film being provided between the stacked layer and the second reflective region.

17. The surface-emitting laser according to claim 1, wherein
the plurality of first structure bodies and the plurality of second structure bodies are arranged in one of a square lattice array, a rectangular lattice array, and a triangular lattice array.

18. The surface-emitting laser according to claim 1, wherein
the light-emitting layer is configured to emit light based on intersubband transition.

19. A method for manufacturing a surface-emitting laser, comprising:
processing a first crystal film using a first mask to form a first crystal layer including a plurality of first structure bodies;
forming a third crystal film on the first crystal layer, a refractive index of the third crystal film being different from a refractive index of the first crystal layer;
planarizing a surface of the third crystal film to form a third crystal layer from the third crystal film;
forming a light-emitting layer on the third crystal layer;
forming a second crystal film on the light-emitting layer;
processing the second crystal film using the first mask to form a second crystal layer including a plurality of second structure bodies; and
forming a fourth crystal layer on the second crystal layer, a refractive index of the fourth crystal layer being different from a refractive index of the second crystal layer.

20. A method for manufacturing a surface-emitting laser, comprising:
preparing a workpiece including a first crystal layer including a plurality of first structure bodies and a third crystal layer provided on the first crystal layer, a refractive index of the third crystal layer being different from a refractive index of the first crystal layer;
forming a light-emitting layer on the third crystal layer;
forming a second crystal film on the light-emitting layer;
processing the second crystal film Oto form a second crystal layer including a plurality of second structure bodies, a second pattern of the plurality of second structure bodies being the same as a first pattern of the plurality of first structure bodies; and
forming a fourth crystal layer on the second crystal layer, a refractive index of the fourth crystal layer being different from a refractive index of the second crystal layer.
